(19) United States
(12) Patent Application Publication
(10) Pub. No.: US 2026/0201999 A1
(43) Pub. Date: Jul. 16, 2026

(54) APPARATUS AND METHOD FOR OPENING A STRIPWOUND HOSE; METHOD FOR THE MAINTENANCE AND/OR REPAIR OF A FIBRE STRAND IN A STRIPWOUND HOSE; USE OF THE APPARATUS AND THE METHODS

(71) Applicant: Carl Zeiss SMT GmbH, Oberkochen (DE)

(72) Inventor: Andreas HOFMAIER, Heidenheim (DE)

(21) Appl. No.: 19/444,495

(22) Filed: Jan. 9, 2026

(30) Foreign Application Priority Data
Jan. 14, 2025 (DE) 10 2025 100 998.8

(51) Int. Cl. F16L 55/16; G02B 6/44

(52) U.S. Cl. CPC F16L 55/16; G02B 6/4486

(57) ABSTRACT

An apparatus can open a desired portion of a stripwound hose which comprises a strip with a plurality of interlocking turns and surrounds an internal fibre strand. The apparatus has a gripping device, with at least a first gripper and a second gripper, for retaining the stripwound hose and an axis of rotation. The portion of the stripwound hose can be positioned on the axis of rotation. The first gripper can be rotated in a first rotational direction about the axis of rotation counter to a winding direction of the stripwound hose, in order to at least partially detach the turns of the stripwound hose so that an inside diameter of the stripwound hose on the portion is increased.

### CROSS-REFERENCE TO RELATED APPLICATION

This application claims benefit under 35 U.S.C. § 119 to German Application No. 10 2025 100 998.8, filed Jan. 14, 2025. The entire disclosure of this application is incorporated by reference herein.

### Field

The disclosure relates to an apparatus for opening a desired portion of a stripwound hose. The disclosure also relates to a method for opening a desired portion of a stripwound hose. The disclosure furthermore relates to a method for maintaining and/or repairing a fibre strand in a desired portion of a stripwound hose. The disclosure further relates to using an apparatus according to the disclosure and/or of a method according to the disclosure for opening a stripwound hose and/or of a method according to the disclosure for maintaining and/or repairing a fibre strand in a stripwound hose, the stripwound hose being located, for example, in a cleanroom environment and/or in a mask inspection system and/or in a lithography system.

### BACKGROUND

Various types of stripwound hoses are known. Stripwound hoses generally comprise (or consist of) a strip with a certain degree of stiffness, but also with a certain degree of flexibility, which is formed into a tubular spiral. This can for example be a wound plastics or metal strip. Stripwound hoses are often used to combine elongate components such as cables or fibre strands and to protect them from external influences, to restrict, among other things, the bending radius and to thereby prevent damage caused by the component buckling. If the internal components are a light guide or a glass fibre, which is operated with high power, the sheathing provided by the stripwound hose can also contribute to protecting against an emergence of light, for example laser radiation, in the event of damage to the light guide or the glass fibre.

For maintenance and/or repair work on the internal components, it may be desirable to open the stripwound hose. For this purpose, it is customary to provide and make use of separation points or coupling points between adjacent segments of the stripwound hose. As a result, the opening position can be relatively limited. During maintenance and/or repair work, it is often desirable to be able to open the stripwound hose at any desired point, for example where the internal component has to be subjected to maintenance and/or repaired. Therefore, the development of alternative apparatuses and methods for opening stripwound hoses on any desired portion of the stripwound hose may be desirable for a great many applications.

A challenge in opening stripwound hoses at any desired point is preventing damage to the internal components, for example when they are relatively sensitive components such as fibre optic cables and/or when the components are not spaced from or have only a small spacing from the surrounding wall. In certain areas of application, for example in cleanroom environments and/or close to optical units, it can be desirable to avoid contamination by particles released during the opening operation. Simply sawing open stripwound hoses is often therefore ruled out for many applications.

DE 10 2019 102 404 A1 discloses an apparatus and a method for cutting a hose which is provided with a reinforcing element and in the lateral surface of which a helical supporting coil, generally comprising (or consisting of) plastic, is embedded. By contrast to a stripwound hose, this is a hose which has a continuous lateral surface and can be used as a hose line, but is not designed to restrict the bending radius. The design provided in DE 10 2019 102 404 A1 of two cutting devices is intended to make it possible, during an ongoing production operation, to completely sever, for example automatedly, a hose provided with a reinforcing element, in spite of the hose being rotated about its longitudinal axis as a result of the way it is produced. However, in general, this cannot be transferred to a stripwound hose used as intended, since a sensitive fibre strand is located inside it.

### SUMMARY

The present disclosure seeks to provide an improved apparatus for opening any desired portion of a stripwound hose, for example allowing the hose to be opened without damaging the internal fibre strand.

In an aspect, the disclosure provides an apparatus for opening a desired portion of a stripwound hose, which comprises a strip with a plurality of interlocking turns and surrounds an internal fibre strand. The apparatus has a gripping device, with at least a first gripper and a second gripper, for retaining the stripwound hose and an axis of rotation. The portion of the stripwound hose can be positioned on the axis of rotation. The first gripper can be rotated in a first rotational direction about the axis of rotation counter to a winding direction of the stripwound hose in order to at least partially detach the turns of the stripwound hose, so that an inside diameter of the stripwound hose on the portion increases.

The present disclosure seeks to provide an method for opening a desired portion of a stripwound hose, for example allowing the hose to be opened without damaging the internal fibre strand.

In an aspect, the disclosure provides a method for opening a desired portion of a stripwound hose which comprises a strip with a plurality of interlocking turns and surrounds an internal fibre strand. At least the following steps are provided: (a) gripping the stripwound hose at a first holding point and at a second holding point and positioning on an axis of rotation the portion of the stripwound hose that lies between the first holding point and the second holding point; (b) rotating the first holding point in a first rotational direction about the axis of rotation counter to a winding direction of the stripwound hose, in order to at least partially detach the turns of the stripwound hose so that an inside diameter of the stripwound hose on the portion is increased.

The present disclosure seeks to provide an improved method for maintaining and/or repairing a fibre strand in any desired portion of a stripwound hose, for example allowing the hose to be opened without damaging the internal fibre strand.

In an aspect, the disclosure provides a method for the maintaining and/or repairing a fibre strand in a desired portion of a stripwound hose, wherein the stripwound hose comprises a strip with a plurality of interlocking turns and the fibre strand is an internal fibre strand surrounded by the stripwound hose. The stripwound hose is located for example in a cleanroom environment, in a mask inspection system and/or in a lithography system. At least the following steps are provided: (a) gripping the stripwound hose at a first holding point and at a second holding point and positioning on an axis of rotation the portion of the stripwound hose that lies between the first holding point and the second holding point; (b) rotating the first holding point in a first rotational direction about the axis of rotation counter to a winding direction of the stripwound hose, in order to at least partially detach the turn of the stripwound hose so that an inside diameter of the stripwound hose on the portion is increased; (c) severing at least one turn of the stripwound hose between the first holding point and the second holding point; (d) carrying out maintenance and/or repair work on the fibre strand located in the open stripwound hose; (e) re-closing the stripwound hose by covering the fibre strand in the opened portion of the stripwound hose with a covering element, such as a metal cannula, and sheathing it with a shrink-fit tube, after which the stripwound hose is closed again, for example crimped together, at the opened portion.

The present disclosure seeks to provide the use of apparatuses and/or methods for opening stripwound hoses and/or of methods for the maintenance and/or repair of fibre strands in stripwound hoses for such stripwound hoses as are located in a cleanroom environment and/or are located in a mask inspection system and/or in a lithography system.

In an aspect, the disclosure provides use of an apparatus according to disclosure, use of a method according to the disclosure for opening a desired portion of a stripwound hose, and/or use of a method according to disclosure for maintaining and/or repairing a fibre strand (5) in a desired portion of a stripwound hose, wherein the stripwound hose is located in a cleanroom environment and/or in a mask inspection system and/or in a lithography system, for example a projection exposure apparatus for semiconductor lithography comprising an illumination system with a radiation source and an optical unit which has at least one optical element.

Embodiments of an apparatus according to the disclosure, of a method according to the disclosure and of a use according to the disclosure are provided, for example, by the disclosure and claims.

An apparatus according to the disclosure for opening a desired portion of a stripwound hose, which comprises a strip with a plurality of interlocking turns and surrounds an internal fibre strand, can have a gripping device, with at least a first gripper and a second gripper, for retaining the stripwound hose and an axis of rotation, wherein the portion of the stripwound hose can be positioned on the axis of rotation. According to the disclosure, the first gripper can be rotated in a first rotational direction about the axis of rotation counter to a winding direction of the stripwound hose, in order to at least partially detach the turns of the stripwound hose so that an inside diameter of the stripwound hose on the portion is increased.

Within the context of the disclosure, a stripwound hose, or spiral hose, is understood for example as meaning a helically or spirally coiled, i.e. wound, strip with a plurality of turns. It can also be multiple jointly wound strips that lie next to one another.

The stripwound hose can be formed by a strip which is interlocked or hooks in itself and is formed into a tubular spiral. For this purpose, the strip can have for example a profile with an S-shaped cross section, a hooked profile or a folded profile. In the example of the S-shaped cross section, when the strip is rolled up, i.e. wound up, one curve of the “S” is interlocked in an inverse curve of the “S” of the adjacent turn. Successive turns can thus be placed one on top of another in the manner of scales. Due to the interlocked state of the turns, a stripwound hose can be generally relatively rigid or stiff in tension, whereas it can be comparatively loose or movable in compression. There can be a seal between the interlocking turns if desired.

The strip from which the stripwound hose is formed typically has a certain degree of stiffness, so it does not unwind again by itself, but has also a certain degree of flexibility. It can be a metal strip, for example a steel strip. An example of a material is stainless steel. The strip can, however, also comprise (or consist of) another material, for example plastic.

A fibre strand can be located in the stripwound hose, such as a fibre optic cable, for example a glass fibre. A fibre strand can be understood as meaning a bundle of multiple fibres or a single fibre. Similarly, a glass fibre can be a bundle of multiple glass fibres or a single glass fibre.

The stripwound hose can restrict the bending radius of the internal fibre strand in normal operation, in order to protect it from damage caused by the fibres buckling and/or breaking. It is generally desirable for the fibre strand to not be damaged or destroyed by the use of the apparatus according to the disclosure when the stripwound hose is being opened.

A typical stripwound hose for use as a sheathing of a fibre strand can have an outside diameter of approximately 1.5 mm to 5 mm. The stripwound hose may, however, have a different outside diameter.

The stripwound hose can combine multiple fibres, for example one to ten fibres, into a bundle. Each fibre or glass fibre can be protected separately by an acrylic coating or an acrylic covering. It is also possible, where appropriate, for only one fibre to be located in the stripwound hose.

If the fibre strand or the glass fibre is used as a fibre optic cable, depending on the context it is possible to provide operation with several watts of power per fibre. In individual cases, the power can also amount to around 50 watts. In those cases, the stripwound hose can also be used as a shield against radiation in the event of damage to the fibre or the fibre strand, in order to avoid or prevent the emergence of radiation and the associated dangers.

An analogous application of the disclosure is conceivable for stripwound hoses that have other internal components, such as cables.

An apparatus according to the disclosure can be suitable for carrying out a method according to the disclosure for opening a stripwound hose, this method being described in more detail below.

It may be desirable to open a stripwound hose for example for maintenance and/or repair purposes, for example in order to inspect, repair and/or replace an internal component such as a fibre strand.

An approach according to the disclosure for opening a stripwound hose makes this possible in a particularly desirable way, for example without damaging internal components such as fibre strands. The inventor has found that the inside diameter of the stripwound hose can be increased by at least partially detaching the turns, i.e. the winding, of the stripwound hose by twisting or rotation or torsion counter to the winding direction. The turns of the strip can be disengaged from one another on the portion to be opened of the stripwound hose by the torsion, with the turns generally curving outwards. The inventor has made use of this to increase the spacing between the fibre strand surrounded by the stripwound hose and the stripwound hose, enabling access to the internal fibre strand without damaging same. If desired, the stripwound hose can be severed after being opened, moreover without damaging the internal fibre strand.

It can be desirable to open a stripwound hose can on any desired portion or at any desired point of the stripwound hose, i.e. is not restricted to separation or coupling points between different segments of the stripwound hose.

During the opening operation, the stripwound hose can “burst open” or “rear up” or radially outwardly “take off” to a certain extent, i.e. that an inside diameter or cross section of the stripwound hose is increased by detaching the turns, so that the previously spirally wound-up strip at least partly no longer has the form of a tube and an opening is produced. Furthermore, the strip can be brought out of its interlocked state. For example, when the wound-up strip of the stripwound hose is a relatively stiff material, such as a metal, it is also possible for loop formation to occur during the opening operation. The opening operation does not automatically lead to the strip being severed; instead, the strip may still be cohesive after being opened.

The gripping device of the apparatus can be used for example to clamp the stripwound hose. The grippers or clamps can engage on a first holding point or a second holding point on the stripwound hose.

A longitudinal axis of the stripwound hose, at least along the portion that is to be opened, can be aligned in such a way that the longitudinal axis lies on the axis of rotation of the apparatus. The axis of rotation is to be understood as meaning an imaginary axis of rotation, i.e. it is not a physical axle or shaft.

The winding direction of the stripwound hose can result from the stripwound hose being produced by the strip being wound up into a spiral or helix. The winding direction therefore extends along the longitudinal axis of the stripwound hose or spirals around the longitudinal axis, either clockwise or anticlockwise. Generally, a turn at least partially overlaps the preceding turn.

The front and the rear end of the stripwound hose are determined by the winding-up order. The end of the stripwound hose at which during production the winding-up process starts, i.e. the end which is wound up first, is referred to as the front end within the context of the disclosure. The end of the stripwound hose at which during production the winding-up process ends, i.e. the end which is wound up last, is referred to as the rear end within the context of the disclosure. The front end thus lies upstream of the rear end, i.e. the rear end lies downstream of the front end.

Generally, in the direction of the rear end, a turn lies at least partially on top of the previous turn, and therefore the turn at the rear end lies on the outside of the winding. The turn at the front end generally lies on the inside.

If the stripwound hose were to be unwound, the unwinding would start with the turn at the rear end. The turn at the front end would be unwound last.

The rotation, i.e. turning, of the first gripper is used for the torsion of the stripwound hose on the portion located between the first gripper and the second gripper. This is assisted by the second gripper also retaining the stripwound hose. The second gripper can either be positionally stable, i.e. rotationally fixed with respect to the axis of rotation, or rotate in an opposite direction, as will be explained in more detail below.

If desired, for example in the case of long stripwound hoses, it may be desirable to conjointly rotate an end portion not located between the grippers, or the extension of the stripwound hose, possibly by hand, in order to avoid excessive twisting or torsion of the stripwound hose in other regions of the stripwound hose. The stripwound hose can be twisted at least approximately exclusively on that portion between the first gripper and the second gripper in which the stripwound hose is to be opened.

It may be provided that the first gripper engages on the stripwound hose downstream of the second gripper as viewed in the winding direction.

This arrangement of the first gripper downstream of the second gripper, i.e. of the second gripper upstream of the first gripper, is generally desirable since the stripwound hose is formed by a strip which is interlocked. Due to the production process, the second turn, as viewed in the winding direction, of the strip of such a stripwound hose is generally partially on top of the first turn of the strip. Therefore the first gripper, which can rotate counter to the winding direction, typically should retain the stripwound hose downstream of the second gripper as viewed in the winding direction to detach the turns. Otherwise, the overlapping turns could make it difficult to detach the turns or prevent them from being detached.

It has proven to be particularly suitable when the first gripper and the second gripper are configured to grip the stripwound hose at an interval of two to five, for example three, turns of the stripwound hose.

It may also be suitable if the first gripper and the second gripper are configured to grip stripwound hose at an interval of 1 cm to 5 cm.

It may further be suitable when the first gripper and the second gripper are configured to grip the stripwound hose at an interval corresponding to one to five times the diameter of the stripwound hose.

The spacing between the grippers can be adjustable.

It may be provided that the second gripper is positionally stable in relation to the axis of rotation and/or the second gripper can be rotated in a second rotational direction about the axis of rotation counter to the first rotational direction of the first gripper.

As a result of the interaction of the first gripper and the second gripper, the torsion of the stripwound hose to open same can be brought about on the portion in question. Without the second gripper, the rotation of the first gripper could cause the torsion of the stripwound hose to spread over an undefined length of the stripwound hose, whereas the combination of the two grippers has the effect of being able to allow a greater torsion of the stripwound hose on the portion between the two grippers. The twisting, which is concentrated on a relatively small region, of the stripwound hose to some extent can form a “predetermined breaking point”, so that the stripwound hose opens just between the two grippers.

In the case of the first alternative, i.e. the simple retention of the stripwound hose by the second gripper, the torsion can result solely from the rotation of the first gripper, since the second gripper is positionally stable, i.e. rotationally fixed, with respect to the axis of rotation. In the case of the second alternative, i.e. the rotation of the grippers in opposite directions, the torsion increases. The second gripper can be configured and designed for both alternatives, so that the more suitable alternative can be selected depending on the use case. At the same time, it is possible for the second gripper to only either be positionally stable or rotate.

In an embodiment, it is provided that the apparatus has an inner part, which can be rotated in the first rotational direction about the axis of rotation and has the first gripper and a through-passage for the stripwound hose. Also provided is an outer part which has the second gripper, wherein the inner part and the outer part are movably connected via a bearing. The outer part can be connected to the fixed world and/or can be rotated counter to the first rotational direction about the axis of rotation.

When the outer part is connected to the fixed world, the second gripper can be positionally stable in relation to the axis of rotation. By contrast, the second gripper can be rotated counter to the first rotational direction, i.e. in the second rotational direction, when the outer part can be rotated counter to the first rotational direction about the axis of rotation. This entails the features described above.

The outer part can be fixed with a fixing mechanism, for example with a screw clamp, and thus connected to the fixed world.

The bearing can help ensure that at least the inner part can be rotated in the first rotational direction about the axis of rotation. The bearing can be for example in the form of a plain bearing and optionally be made of a plastic alloy based on thermoplastic materials. In addition, lubricants may optionally be applied to the contact surfaces of the bearing to further reduce the friction. Instead of a plain bearing, it can also be a different type of bearing.

The rotatable inner part can have a tool interface, for example a ring of holes for introducing an elongate tool that acts as a lever, for the purpose of making the rotation easier. If desired, a motor may also be provided for the rotation of the inner part.

The through-passage for the stripwound hose can be a continuous cavity suitable for the passage of the stripwound hose. In this case, the axis of rotation of the apparatus, i.e. of the inner part, can coincide with a longitudinal axis of the through-passage. The grippers or the holding points formed by the grippers can be located at least approximately on the axis of rotation or in the extension of the longitudinal axis of the through-passage or the axis of rotation of the inner part.

Optionally, the grippers are not located inside the through-passage but in the extension of the longitudinal axis of the through-passage. The grippers can be spaced from the through-passage to different extents.

The stripwound hose can be routed through the through-passage in such a way that the first gripper retains the stripwound hose downstream of the second gripper, or the second gripper retains same upstream of the first gripper, as viewed in the winding direction.

If the stripwound hose is particularly long and/or has no free end, the stripwound hose can if desired be routed in the form of a loop through the through-passage.

It has proven to be particularly suitable when the first gripper and the second gripper can be rotated by 180° to 540°, such as by 270° to 450°, relative to one another about the axis of rotation.

The total rotation can result either only from the rotation of the first gripper in the first rotational direction or from the combination of the rotation of the first gripper and the rotation of the second gripper in the opposite second rotational direction.

Depending on the configuration of the stripwound hose that is to be opened, it can for example be opened during a rotation of for instance 440° of the grippers with respect to one another. The exact torsion can be matched to the respective stripwound hose.

It may be provided that the first gripper and/or the second gripper are in two parts, if appropriate also multiple parts. The respective gripper can have two gripper parts between which the stripwound hose can be positioned, for example clamped. The two gripper parts of the respective gripper can be force-lockingly and/or form-fittingly fixable and/or connectable, for example using fastening elements such as screws.

It may be desirable if the first gripper and/or the second gripper has, in the longitudinal direction of the apparatus, i.e. parallel to the axis of rotation, an elongate depression for receiving the stripwound hose.

This can help ensure a good distribution of the pressure exerted by the grippers on the stripwound hose together with a rotationally fixed attachment.

The depression, or notch or groove, can be semicircular in cross section, the radius optionally corresponding at least approximately to the radius of the stripwound hose that is to be opened. This can help make it possible to provide a relatively large contact surface for attachment.

It may be provided that the first gripper and/or the second gripper of the apparatus can be exchanged, for example with another first or second gripper, respectively, the depression of which has a different radius.

It may also be desirable if the second gripper has an indentation at an end facing towards the first gripper.

This indentation can be used to make it easier to detach the turns on the portion of the stripwound hose between the first gripper and the second gripper. For example, the indentation creates a space in order to permit an increase in the inside diameter and thus also the outside diameter of the stripwound hose, i.e. an increase in the cross section of the stripwound hose, when the previously wound-up strip curves outwards as it is opened.

If desired, the indentation can supplement, i.e. radially extend, the depression in the second gripper.

As an alternative and/or in addition, it can correspondingly and analogously also be provided that the first gripper has an indentation at an end facing towards the second gripper.

In a development of the apparatus according to the disclosure, a cutting device may be provided in order to sever at least one turn after the stripwound hose has been opened.

Cutting open the stripwound hose can help make it even easier to access the internal fibre strand. For example, this makes it possible to push the stripwound hose, which is in two parts as a result, away from the interface in both directions along its longitudinal axis, so that the underlying fibre strand is exposed. Furthermore, this also makes it possible to reach a point of the fibre strand that is not positioned directly underneath the opening in the stripwound hose.

The cutting device can be a conventional side cutter.

Depending on how the strip outwardly curves or bends when the stripwound hose is being opened or how loops that might be formed align, it may be desirable to firstly remove the stripwound hose by detaching the grippers from the apparatus in order to then be able to sever the strip unobstructed without damaging the fibre strand.

The apparatus can be configured and designed for example to open a stripwound hose of which the strip is formed by a metal strip, for example a steel strip.

If the strip is made of a metal, the stripwound hose can have a relatively high stability. Due to its non-combustible properties, metal can be suitable for example for the sheathing of fibre optic cables or glass fibres that are operated with high power. In addition, metal can be a material in cleanroom environments and/or vacuum environments, since for example no evaporation is expected.

In an embodiment, the internal fibre strand is formed by a fibre optic cable, for example a glass fibre, and the apparatus is configured and designed to open the stripwound hose in such a way that the fibre optic cable or the glass fibre remains undamaged while the stripwound hose is being opened.

The disclosure also relates to a method for opening any desired portion of a stripwound hose which comprises a strip with a plurality of interlocking turns and surrounds an internal fibre strand, wherein at least the following steps are provided:
(a) gripping the stripwound hose at a first holding point and at a second holding point and positioning on an axis of rotation the portion of the stripwound hose that lies between the first holding point and the second holding point;
(b) rotating the first holding point in a first rotational direction about the axis of rotation counter to a winding direction of the stripwound hose, in order to at least partially detach the turns of the stripwound hose so that an inside diameter of the stripwound hose on the portion is increased.

A method according to the disclosure can be carried out particularly via an apparatus according to the disclosure, as described above, for opening a stripwound hose. The features of a method according to the disclosure arise analogously from the already described features. However, a method according to the disclosure is not limited to the use of an apparatus according to the disclosure, but can also be implemented independently.

Within the context of this disclosure, the holding points are not points in the geometrical sense, but holding regions. The holding points can be formed by a surface of contact of each gripper with the stripwound hose, these surfaces of contact being used to hold, i.e. grip, the stripwound hose.

It can be provided in the course of the method that in step (a), the first holding point is downstream of the second holding point as viewed in the winding direction.

It has proved particularly suitable when in step (a) the stripwound hose is gripped at an interval of two to five, such as three, turns of the stripwound hose.

It may be provided that during step (b) the second holding point is held positionally stably, i.e. rotationally fixedly, in relation to the axis of rotation or rotated in a second rotational direction about the axis of rotation counter to the first rotational direction.

It has been shown that it can be particularly suitable when during step (b) the first holding point and the second holding point are rotated by 180° to 540°, such as by 270° to 450°, relative to one another.

In a development of a method, a further step may be provided:
(c) severing at least one turn of the stripwound hose between the first holding point and the second holding point.

Subsequently, the fibre strand can be further exposed at least along a partial length of the portion, for example by cutting through or severing further turns and/or by pushing two resulting parts of the stripwound hose away from the interface in opposite directions along the longitudinal axis of the stripwound hose.

The strip of the stripwound hose can be formed by a metal strip, for example a steel strip.

The method has proven desirable for example when the internal fibre strand is formed by a fibre optic cable, for example a glass fibre, wherein steps (a) and (b) and, if appropriate, (c) are carried out in such a way that the fibre optic cable or the glass fibre remains undamaged while the stripwound hose is being opened.

If desired, a further step may be provided:
(d) carrying out maintenance and/or repair work on the fibre strand located in the open stripwound hose.

This can help expand the method for opening the stripwound hose to a maintenance method, i.e. the opening method can be construed as such.

Depending on the purpose or desire, maintenance and/or repair work on a fibre strand may comprise for example the following sub-steps:
removing an acrylic coating which might be present around the fibre strand or its individual fibres;
lopping off the fibre strand or the individual fibres thereof;
welding two parts of fibre strands or fibres to one another.

The above enumeration should not be construed as exhaustive.

In order to carry out maintenance and/or repair work on a fibre strand, it might moreover be desirable to shift the opening of the stripwound hose provided by the method according to the disclosure from its original position to that point of the fibre strand at which the maintenance and/or repair work is to be carried out. For this purpose, one part of the stripwound hose can if desired be compressed, while the other part is stretched.

A further step may be provided:
(e) re-closing the stripwound hose by covering the fibre strand in the opened portion of the stripwound hose with a metal cannula, after which the fibre strand and the metal cannula are sheathed with a shrink-fit tube, after which the stripwound hose is closed again, such as crimped together, at the opened portion.

To re-close the stripwound hose, it can be desirable to first clean up, trim and/or lop off the edges, for example cut edges, at the opening in order to obtain a good transition point.

The covering or sheathing of the fibre-strand region subjected to maintenance or repair with a metal cannula or a shrink-fit tube can be carried out over a length which is sufficient to prevent inadvertent unwinding of the stripwound hose, for example over a length of 2 cm to 5 cm.

The crimping can be carried out using conventional crimping tools.

It has proven to be particularly desirable when an apparatus according to the disclosure as per the preceding description is used to carry out the method according to the disclosure.

The disclosure furthermore relates to a method for the maintenance and/or repair of a fibre strand in any desired portion of a stripwound hose, wherein the stripwound hose comprises a strip with a plurality of interlocking turns and the fibre strand is an internal fibre strand surrounded by the stripwound hose, wherein the stripwound hose is located for example in a cleanroom environment, in a mask inspection system and/or in a lithography system. In this case, at least the following steps are provided:
(a) gripping the stripwound hose at a first holding point and at a second holding point and positioning on an axis of rotation the portion of the stripwound hose that lies between the first holding point and the second holding point;
(b) rotating the first holding point in a first rotational direction about the axis of rotation counter to a winding direction of the stripwound hose, in order to at least partially detach the turns of the stripwound hose so that an inside diameter of the stripwound hose on the portion is increased;
(c) severing at least one turn of the stripwound hose between the first holding point and the second holding point;
(d) carrying out maintenance and/or repair work on the fibre strand located in the open stripwound hose;
(e) re-closing the stripwound hose by covering the fibre strand in the opened portion of the stripwound hose with a covering element, such as with a metal cannula, and sheathing it with a shrink-fit tube, after which the stripwound hose is closed again, for example crimped together, at the opened portion.

The features of a method according to the disclosure for the maintenance and/or repair of a fibre strand in a stripwound hose arise analogously from the above-described features of the apparatus according to the disclosure and the method according to the disclosure for opening a stripwound hose. The additional steps also can help ensure that the fibre strand is functional again after completion of the maintenance and/or repair method and that the stripwound hose is properly closed again.

This method can also be carried out using an apparatus according to the disclosure.

The steps of the methods can be carried out in the specified alphabetical order, from (a) to (e). Further steps and/or intermediate steps may be provided.

The disclosure further relates to the use of an apparatus according to the disclosure for opening any desired portion of a stripwound hose and/or of a method according to the disclosure for opening any desired portion of a stripwound hose and/or of a method according to the disclosure for the maintenance and/or repair of a fibre strand in any desired portion of a stripwound hose as per the description of each given above, wherein the stripwound hose is located in a cleanroom environment and/or in a mask inspection system and/or in a lithography system, for example a projection exposure apparatus for semiconductor lithography, comprising an illumination system with a radiation source and an optical unit, which has at least one optical element.

The features of a use according to the disclosure of an apparatus according to the disclosure and/or methods according to the disclosure arise analogously from the above-described features of the apparatus according to the disclosure and of the methods according to the disclosure.

A cleanroom environment can also be understood as meaning a vacuum environment.

The mask inspection system can for example be used to inspect or measure photomasks or reticles prior to their intended use or prior to their integration in an optical system, for example a lithography system. The lithography system may for example be a projection exposure apparatus for semiconductor lithography, which is operated using EUV (extreme ultraviolet) light or using DUV (deep ultraviolet) light.

In general, the disclosure may be suitable for use in the case of stripwound hoses used in the immediate vicinity of sensitive optical units, for example in lenses.

In the above-mentioned use cases, it can be desirable to avoid contamination of the surrounding area when stripwound hoses are being opened. The disclosure can make it possible to largely avoid the undesirable release of particles or fine dust as would arise for example from a sawing-open operation.

Features described in conjunction with one of the subjects of the disclosure, specifically given by an apparatus according to the disclosure, methods according to the disclosure or the use according to the disclosure, are also implementable for the other subjects of the disclosure. Likewise, features specified in conjunction with one of the subjects of the disclosure can also be understood in relation to the other subjects of the disclosure.

Additionally, it should be noted that terms such as “comprising”, “having”, or “with” do not exclude other features or steps. Furthermore, terms such as “a(n)” or “the” which indicate single steps or features do not exclude a plurality of features or steps-and vice versa.

However, in a puristic embodiment of the disclosure, provision may also be made for the features introduced in the disclosure using the terms “comprising”, “having”, or “with” to be an exhaustive enumeration. Accordingly, one or more enumerations of features can be considered to be exhaustive within the context of the disclosure, for example respectively considered for each claim. For example, the disclosure can consist exclusively of the features specified in a given embodiment.

It should be noted that designations such as “first” or “second”, etc. are used predominantly to be able to distinguish between respective apparatus or method features and are not necessarily intended to indicate that features require one another or are related to one another.

Exemplary embodiments of the disclosure will be described in more detail below with reference to the drawing.

The figures each show certain exemplary embodiments in which individual features of the present disclosure are illustrated in combination with one another. Features of an exemplary embodiment are also implementable independently of the other features of the same exemplary embodiment, and may readily be combined accordingly by a person skilled in the art to form further viable combinations and sub-combinations with features of other exemplary embodiments.

### BRIEF DESCRIPTION OF THE DRAWINGS

In the figures, functionally identical elements are given the same reference signs.

In the figures:

FIG. 1 shows a meridional section of an EUV projection exposure apparatus;

FIG. 2 shows a DUV projection exposure apparatus;

FIG. 3 shows a perspective view of an exemplary embodiment of an apparatus according to the disclosure;

FIG. 4 shows a basic cross-sectional view of the apparatus according to FIG. 3;

FIG. 5 shows a perspective view of the second gripper of the apparatus according to FIG. 3 in the open state;

FIG. 6 shows a plan view of the lower gripper part of the second gripper according to FIG. 5;

FIG. 7 shows a basic illustration of the overall structure of a stripwound hose with an internal fibre strand;

FIG. 8 shows a basic illustration, in cross section, of an exemplary stripwound hose with an internal fibre strand;

FIG. 9 shows a basic illustration of an exemplary profiled strip for a stripwound hose; and

FIG. 10 shows a basic illustration, in cross section, of three exemplary profiles of strips for a stripwound hose.

### DETAILED DESCRIPTION

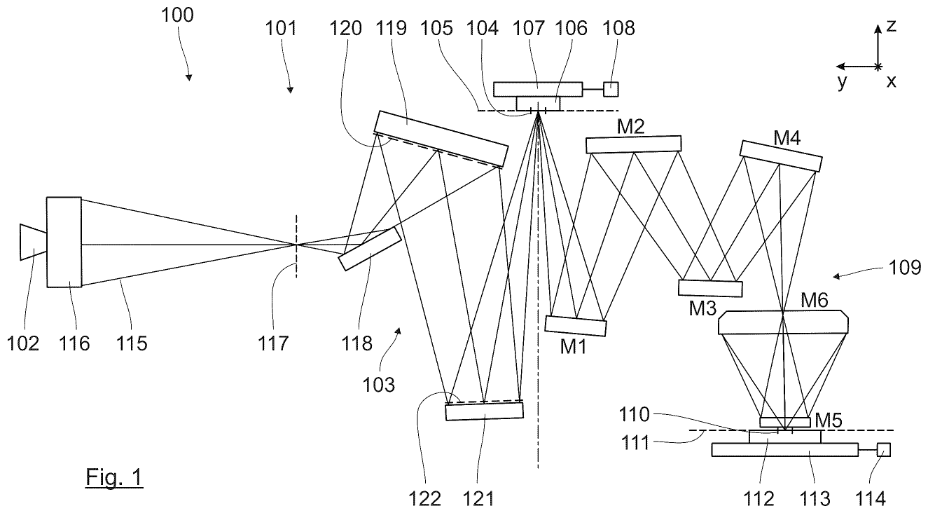

With reference to FIG. 1, certain component parts of a microlithographic EUV projection exposure apparatus 100 as an example of a lithography system are initially described below in exemplary fashion. The description of the basic construction of the EUV projection exposure apparatus 100 and of the component parts thereof should not be interpreted restrictively here.

An illumination system 101 of the EUV projection exposure apparatus 100 comprises, besides a radiation source 102, an illumination optical unit 103 for the illumination of an object field 104 in an object plane 105. In this case, a reticle 106 arranged in the object field 104 is exposed. The reticle 106 is held by a reticle holder 107. The reticle holder 107 is displaceable for example in a scanning direction by way of a reticle displacement drive 108.

FIG. 1 depicts a Cartesian xyz-coordinate system for illustrative purposes The x-direction runs perpendicularly into the plane of the drawing. The y-direction runs horizontally, and the z-direction runs vertically. In FIG. 1, the scanning direction runs in the y-direction. The z-direction runs perpendicularly to the object plane 105.

The EUV projection exposure apparatus 100 comprises a projection optical unit 109. The projection optical unit 109 serves for imaging the object field 104 into an image field 110 in an image plane 111. The image plane 111 runs parallel to the object plane 105. As an alternative, an angle between the object plane 105 and the image plane 111 that differs from 0° is also possible.

A structure on the reticle 106 is imaged onto a light-sensitive layer of a wafer 112 arranged in the region of the image field 110 in the image plane 111. The wafer 112 is held by a wafer holder 113. The wafer holder 113 is displaceable for example along the y-direction by way of a wafer displacement drive 114. The displacement, firstly, of the reticle 106 by way of the reticle displacement drive 108 and, secondly, of the wafer 112 by way of the wafer displacement drive 114 can be synchronized with one another.

The radiation source 102 is an EUV radiation source. The radiation source 102 emits for example EUV radiation 115, which in the following text is also referred to as used radiation or illumination radiation. For example, the used radiation 115 has a wavelength in the range between 5 nm and 30 nm. The radiation source 102 can be a plasma source, for example an LPP source (“laser produced plasma”) or a GDPP source (“gas discharge produced plasma”). It may also be a synchrotron-based radiation source. The radiation source 102 can be a free electron laser (FEL).

The illumination radiation 115 emanating from the radiation source 102 is focused by a collector 116. The collector 116 may be a collector with one or more ellipsoidal and/or hyperboloidal reflection surfaces. The at least one reflection surface of the collector 116 can be impinged upon by the illumination radiation 115 with grazing incidence (GI), i.e. with angles of incidence greater than 45°, or with normal incidence (NI), i.e. with angles of incidence less than 45°. The collector 116 can be structured and/or coated, firstly to optimize its reflectivity for the used radiation 115 and secondly to suppress extraneous light.

Downstream of the collector 116, the illumination radiation 115 propagates through an intermediate focus in an intermediate focal plane 117. The intermediate focal plane 117 may represent a separation between a radiation source module, comprising the radiation source 102 and the collector 116, and the illumination optical unit 103.

The illumination optical unit 103 comprises a deflection mirror 118 and, disposed downstream thereof in the beam path, a first facet mirror 119. The deflection mirror 118 may be a planar deflection mirror or alternatively a mirror with a beam-influencing effect that goes beyond the pure deflection effect. Alternatively or additionally, the deflection mirror 118 may take the form of a spectral filter that separates a used light wavelength of the illumination radiation 115 from extraneous light having a wavelength that deviates therefrom. If the first facet mirror 119 is arranged in a plane of the illumination optics unit 103 that is optically conjugate to the object plane 105 as a field plane, it is also referred to as a field facet mirror. The first facet mirror 119 comprises a multiplicity of individual first facets 120, which are also referred to below as field facets. Only a few of these facets 120 are illustrated in FIG. 1 by way of example.

The first facets 120 may be in the form of macroscopic facets, for example rectangular facets or facets with an arc-shaped edge contour or part-circle-shaped edge contour. The first facets 120 may be in the form of planar facets or, alternatively, of convexly or concavely curved facets.

As is known for example from DE 10 2008 009 600 A1, the first facets 120 themselves may each also be composed of a multiplicity of individual mirrors, for example a multiplicity of micromirrors. The first facet mirror 119 may for example be in the form of a microelectromechanical system (MEMS system). For details, reference is made to DE 10 2008 009 600 A1.

The illumination radiation 115 travels horizontally, i.e. in the y-direction, between the collector 116 and the deflection mirror 118.

In the beam path of the illumination optical unit 103, a second facet mirror 121 is arranged downstream of the first facet mirror 119. If the second facet mirror 121 is arranged in a pupil plane of the illumination optical unit 103, it is also referred to as a pupil facet mirror. The second facet mirror 121 can also be arranged at a distance from a pupil plane of the illumination optical unit 103. In this case, the combination of the first facet mirror 119 and the second facet mirror 121 is also referred to as a specular reflector. Specular reflectors are known from US 2006/0132747 A1, EP 1 614 008 B1 and US 6,573,978.

The second facet mirror 121 comprises a plurality of second facets 122. In the case of a pupil facet mirror, the second facets 122 are also referred to as pupil facets.

The second facets 122 may also be macroscopic facets, which may for example have a round, rectangular or hexagonal boundary, or may alternatively be facets composed of micromirrors. In this regard, reference is likewise made to DE 10 2008 009 600 A1.

The second facets 122 can have plane or alternatively convexly or concavely curved reflection surfaces.

The illumination optical unit 103 thus forms a doubly faceted system. This basic principle is also referred to as fly's eye integrator.

It can be desirable to arrange the second facet mirror 121 not exactly in a plane that is optically conjugate to a pupil plane of the projection optical unit 109.

The second facet mirror 121 is used to image the individual first facets 120 into the object field 104. The second facet mirror 121 is the last beam-shaping mirror or actually the last mirror for the illumination radiation 115 in the beam path upstream of the object field 104.

In a further embodiment (not illustrated) of the illumination optical unit 103, a transfer optical unit contributing for example to the imaging of the first facets 120 into the object field 104 may be arranged in the beam path between the second facet mirror 121 and the object field 104. The transfer optical unit can have exactly one mirror, or alternatively two or more mirrors arranged one behind another in the beam path of the illumination optical unit 103. For example, the transfer optical unit can comprise one or two normal incidence mirrors (NI mirrors) and/or one or two grazing incidence mirrors (GI mirrors).

In the embodiment shown in FIG. 1, the illumination optical unit 103 has exactly three mirrors downstream of the collector 116, specifically the deflection mirror 118, the field facet mirror 119 and the pupil facet mirror 121.

In a further embodiment of the illumination optical unit 103, the deflection mirror 118 may also be omitted, and so the illumination optical unit 103 may then have exactly two mirrors downstream of the collector 116, specifically the first facet mirror 119 and the second facet mirror 121.

The imaging of the first facets 120 into the object plane 105 via the second facets 122 or using the second facets 122 and a transfer optical unit is generally only approximate imaging.

The projection optical unit 109 comprises a plurality of mirrors Mi, which are numbered in accordance with their arrangement in the beam path of the EUV projection exposure apparatus 100.

In the example illustrated in FIG. 1, the projection optical unit 109 comprises six mirrors M1 to M6. Alternatives with four, eight, ten, twelve or any other number of mirrors Mi are also possible. The penultimate mirror M5 and the last mirror M6 each have a through opening for the illumination radiation 115. The projection optics unit 109 is a doubly obscured optics unit. The projection optical unit 109 has an image-side numerical aperture which is greater than 0.5 and may also be greater than 0.6 and may for example be 0.7 or 0.75.

Reflection surfaces of the mirrors Mi may take the form of free-form surfaces without an axis of rotational symmetry. Alternatively, the reflection surfaces of the mirrors Mi may be designed as aspheric surfaces with exactly one axis of rotational symmetry of the reflection surface shape. Just like the mirrors of the illumination optical unit 103, the mirrors Mi may comprise highly reflective coatings for the illumination radiation 115. These coatings may be in the form of multilayer coatings, for example with alternating layers of molybdenum and silicon.

The projection optical unit 109 has a large object-image shift in the y-direction between a y-coordinate of a centre of the object field 104 and a y-coordinate of the centre of the image field 110. This object-image shift in the y-direction may have approximately the same magnitude as a z-distance between the object plane 105 and the image plane 111.

The number of intermediate image planes in the x-direction and in the y-direction in the beam path between the object field 104 and the image field 110 can be the same or can, depending on the embodiment of the projection optical unit 109, be different. Examples of projection optics units with different numbers of such intermediate images in the x-and y-directions are known from US 2018/0074303 A1.

A respective one of the pupil facets 122 is assigned to exactly one of the field facets 120, in each case to form an illumination channel for illuminating the object field 104. For example, this may result in illumination according to the Köhler principle. The far field is decomposed into a plurality of object fields 104 with the aid of the field facets 120. The field facets 120 generate a plurality of images of the intermediate focus on the pupil facets 122 respectively assigned thereto.

The field facets 120 are each imaged by an assigned pupil facet 122 onto the reticle 106 in a manner overlaid on one another in order to illuminate the object field 104. The illumination of the object field 104 is for example as homogeneous as possible. It can have a uniformity error of less than 2%. Field uniformity can be achieved by overlaying different illumination channels.

The illumination of the entrance pupil of the projection optical unit 109 may be defined geometrically by way of an arrangement of the pupil facets. The intensity distribution in the entrance pupil of the projection optical unit 109 can be set by selecting the illumination channels, for example the subset of the pupil facets that guide light. This intensity distribution is also referred to as illumination setting.

A likewise preferred pupil uniformity in the region of portions of an illumination pupil of the illumination optical unit 103 that are illuminated in a defined manner can be attained by a redistribution of the illumination channels.

Further aspects and details of the illumination of the object field 104 and for example of the entrance pupil of the projection optical unit 109 are described below.

The projection optical unit 109 can have for example a homocentric entrance pupil. The latter may be accessible. It may also be inaccessible.

The entrance pupil of the projection optical unit 109 cannot, as a rule, be exactly illuminated using the pupil facet mirror 121. The aperture rays often do not intersect at a single point when the imaging by the projection optical unit 109 telecentrically images the centre of the pupil facet mirror 121 onto the wafer 112. However, it is possible to find an area in which the spacing of the aperture rays, which is determined in pairs, becomes minimal. This area is the entrance pupil or an area conjugate thereto in real space. For example, this area has a finite curvature.

It may be the case that the projection optical unit 109 has different positions of the entrance pupil for the tangential beam path and for the sagittal beam path. In this case, an imaging element, for example an optical component of the transfer optical unit, should be provided between the second facet mirror 121 and the reticle 106. With the aid of this optical structural element, it is possible to take account of the different position of the tangential entrance pupil and the sagittal entrance pupil.

In the arrangement of the components of the illumination optical unit 103 illustrated in FIG. 1, the pupil facet mirror 121 is arranged in an area conjugate to the entrance pupil of the projection optical unit 109. The first field facet mirror 119 is tilted with respect to the object plane 105. The first facet mirror 119 is tilted with respect to an arrangement plane defined by the deflection mirror 118.

The first facet mirror 119 is tilted in relation to an arrangement plane defined by the second facet mirror 121.

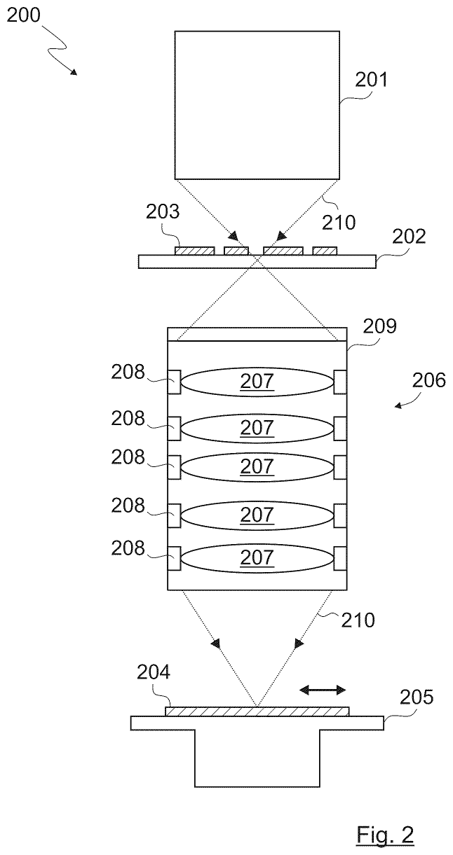

FIG. 2 shows an exemplary DUV projection exposure apparatus 200. The DUV projection exposure apparatus 200 comprises an illumination system 201, a device known as a reticle stage 202 for receiving and exactly positioning a reticle 203 by which the later structures on a wafer 204 are determined, a wafer holder 205 for holding, moving, and exactly positioning the wafer 204, and an imaging device, specifically a projection optical unit 206, with a plurality of optical elements, for example lens elements 207, which are held by way of mounts 208 in a lens housing 209 of the projection optical unit 206.

As an alternative or in addition to the lens elements 207 illustrated, provision may be made of various refractive, diffractive and/or reflective optical elements, inter alia also mirrors, prisms, terminating plates, and the like.

The basic functional principle of the DUV projection exposure apparatus 200 makes provision for the structures introduced into the reticle 203 to be imaged onto the wafer 204.

The illumination system 201 provides a projection beam 210 in the form of electromagnetic radiation, which is used for the imaging of the reticle 203 onto the wafer 204. The source used for this radiation may be a laser, a plasma source, or the like. The radiation is shaped in the illumination system 201 via optical elements such that the projection beam 210 has the desired properties with regard to diameter, polarization, shape of the wavefront, and the like when it is incident on the reticle 203.

Using the projection beam 210, an image of the reticle 203 is created and transferred from the projection optical unit 206 onto the wafer 204 in an appropriately reduced form. In this case, the reticle 203 and the wafer 204 can be moved synchronously, so that regions of the reticle 203 are imaged onto corresponding regions of the wafer 204 virtually continuously during what is called a scanning operation.

An air gap between the last lens element 207 and the wafer 204 can optionally be replaced by a liquid medium which has a refractive index of greater than 1.0. The liquid medium can be, for example, high-purity water. Such a construction is also referred to as immersion lithography and has an increased photolithographic resolution.

The use of the disclosure is not restricted to use in projection exposure apparatuses 100, 200, for example also not with the described construction. The disclosure is suitable for any desired lithography systems or microlithography systems, but for example for projection exposure apparatuses having the described construction. The disclosure is also suitable for EUV projection exposure apparatuses which have a smaller image-side numerical aperture than that described in connection with FIG. 1, and have no obscured mirror M5 and/or M6. For example, the disclosure is also suitable for EUV projection exposure apparatuses which have an image-side numerical aperture from 0.25 to 0.5, such as 0.3 to 0.4, for example 0.33. The disclosure and the subsequent exemplary embodiments should also not be understood as being restricted to a specific design.

The figures that follow illustrate the disclosure merely by way of example and in highly schematized form.

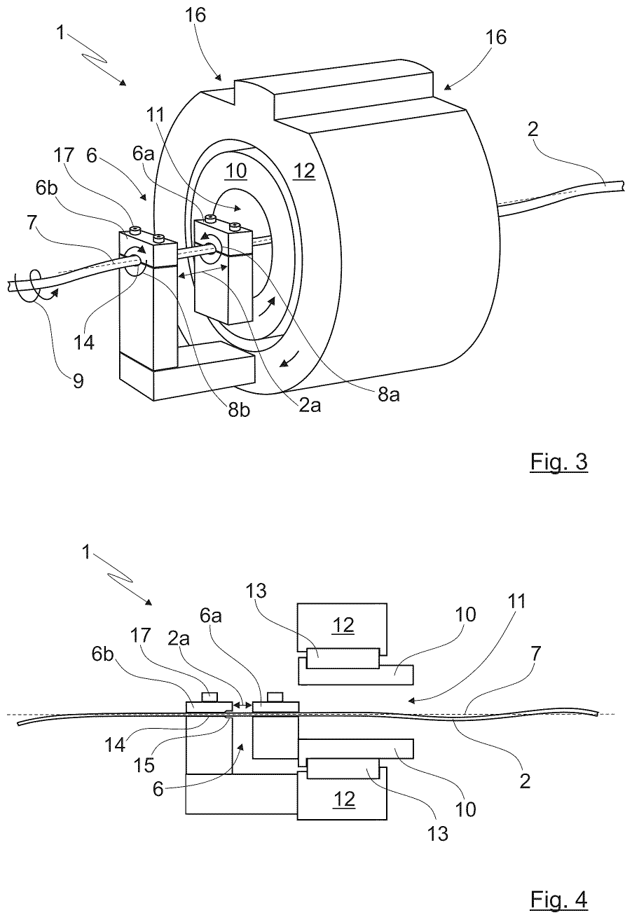

FIG. 3 shows a perspective view of one embodiment of an apparatus 1 according to the disclosure for opening any desired portion 2a of a stripwound hose 2, wherein the stripwound hose 2 comprises a strip 3 with a plurality of interlocking turns 4 and surrounds an internal fibre strand 5. The basic structure of stripwound hoses 2 is explained in greater detail below with reference to FIGS. 7 to 10. FIG. 3 does not show any details of the stripwound hose 2, for example does not show the strip 3, the turns 4 and the internal fibre strand 5.

The apparatus 1 according to the disclosure has a gripping device 6, with at least a first gripper 6a and a second gripper 6b, for retaining the stripwound hose 2 and an axis of rotation 7, wherein the portion 2a of the stripwound hose 2 can be positioned on the axis of rotation 7. The first gripper 6a can be rotated in a first rotational direction 8a about the axis of rotation 7 counter to a winding direction 9 of the stripwound hose 2, in order to at least partially detach the turns 4 of the stripwound hose 2 so that an inside diameter 2b of the stripwound hose 2 on the portion 2a is increased. The axis of rotation 7 is indicated in FIG. 3 by a dashed line. The first rotational direction 8a and the winding direction 9 are each symbolized by arrows. The winding direction 9 in FIG. 3 corresponds to the winding direction 9 in the schematic illustration of the stripwound hose 2 with the inside diameter 2b in FIG. 7, and also to the exemplary embodiment according to FIG. 8, as will also be explained below.

The apparatus 1 according to the disclosure, as illustrated by way of example in FIG. 3, allows the opening of any desired portion 2a of a stripwound hose 2, i.e. not just at the intended separation or coupling points between different segments of the stripwound hose 2. Moreover, possible damage to or destruction of the internal fibre strand 5 can be avoided in a particularly desirable way. According to the disclosure, the stripwound hose 2 is opened by the rotation or torsion of the stripwound hose 2 counter to its winding direction 9 on the portion 2a that is to be opened of the stripwound hose 2, this portion being located between the first gripper 6a and the second gripper 6b.

When the apparatus 1 according to the disclosure as per FIG. 3 is used as intended, in addition to the portion 2a between the grippers 6a, 6b for example that part of the stripwound hose 2 that is shown on the right-hand side of the gripping device 6 can also rotate, i.e. conjointly rotate.

The first gripper 6a can engage on the stripwound hose 2 downstream of the second gripper 6b as viewed in the winding direction 9. This is also illustrated in FIG. 8, which is described in greater detail below.

It has proven to be particularly suitable when the first gripper 6a and the second gripper 6b grip the stripwound hose 2 at an interval of two to five, such as three, turns of the stripwound hose 2. Reference should also be made to FIG. 8 and the associated description in this regard.

It may be provided that the second gripper 6b is positionally stable or rotationally fixed in relation to the axis of rotation 7 and/or the second gripper 6b can be rotated in a second rotational direction 8b about the axis of rotation 7 counter to the first rotational direction 8a of the first gripper 6a. The apparatus 1 can be designed for both alternatives.

In an embodiment of the apparatus 1, an inner part 10 of the apparatus 1 that can be rotated in the first rotational direction 8a about the axis of rotation 2 is provided, as indicated in FIG. 3 by an arrow, this inner part having the first gripper 6a and a through-passage 11 for the stripwound hose 7, and an outer part 12 of the apparatus 1 is provided, this outer part having the second gripper 6b. This is shown by way of example in FIG. 3. The inner part 10 and the outer part 12 are movably connected via a bearing 13. The bearing 13 is not visible in FIG. 3. In this regard, reference should be made to FIG. 4, which is explained in greater detail below.

The outer part 12 can be connected to the fixed world and/or can be rotated counter to the first rotational direction 8a about the axis of rotation 7. This is symbolized by the arrow in FIG. 3. The second gripper 6b and the outer part 12 of the apparatus 1 can, however, as mentioned, also be positionally stable, i.e. connected to the fixed world. For this purpose, the outer part 12 according to FIG. 3 has on its top side one or more fixing points, in the exemplary embodiment two grooves 16, i.e. shoulders or depressions, which can be used to clamp the apparatus 1, for example in a conventional vice or another fixing device.

It has proven to be desirable for the first gripper 6a and the second gripper 6b to be rotated by 180° to 540°, such as by 270° to 450°, relative to one another about the axis of rotation 7.

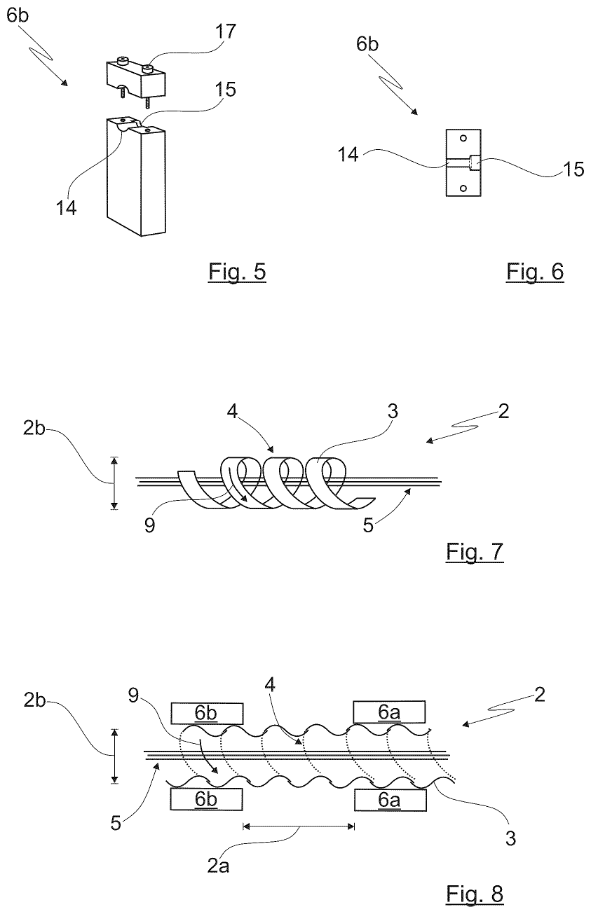

The first gripper 6a and/or the second gripper 6b can be formed in two parts, as depicted in FIG. 3 and also in FIGS. 5 and 6. The two gripper parts of the respective gripper 6a, 6b can be fixed by fastening elements, such as screws 17, optionally on either side of the stripwound hose 2, as a result of which the stripwound hose 2 is clamped between the two gripper parts.

The first gripper 6a and/or the second gripper 6b can have, in the longitudinal direction of the apparatus 1, i.e. of the axis of rotation 7, an elongate depression 14 for receiving the stripwound hose 2.

The second gripper 6b may have an indentation 15 at its end facing towards the first gripper 6a, i.e. in the direction of the first gripper 6a. For an exemplary illustration of the indentation 15, reference should be made to FIGS. 4, 5 and 6.

A cutting device may be provided, in order to sever at least one turn 4 after the stripwound hose 2 has been opened. The cutting device, which is not illustrated in the drawing, can for example be a conventional side cutter.

It can be desirable for the apparatus 1 to be configured and designed to open a stripwound hose 2 of which the strip 3 is formed by a metal strip, for example a steel strip.

It can also be desirable for the apparatus 1 to be configured and designed to open a stripwound hose 2 of which the internal fibre strand 5 is formed by a fibre optic cable, for example a glass fibre, in such a way that the fibre optic cable or the glass fibre remains undamaged when the stripwound hose 2 is being opened.

FIG. 4 shows a basic cross-sectional view of the embodiment of the apparatus 1 according to the disclosure as per FIG. 3, the illustration not being true to scale. This view shows the bearing 13, which is located between the inner part 10 and the outer part 12 of the apparatus 1. The bearing 13 can be in the form of a plain bearing. Also visible in the view of FIG. 4 is the indentation 15 of the second gripper 6b, the second indentation radially extending the depression 14.

The aspects that are not described in more detail in relation to FIG. 4 are similar to the description of FIG. 3.

FIG. 5 shows a perspective view of the second gripper 6b of the apparatus 1 according to FIG. 3 in the open state. The other component parts of the apparatus 1 are not depicted in FIG. 5. In the exemplary embodiment, the grippers are two-part grippers 6a, 6b with an upper and a lower gripper part. In FIG. 5, the screws 17 with which the two gripper parts can be fixed have been loosened and the upper gripper part has been lifted upwards. In this state, a stripwound hose 2 can be laid into the elongate depression 14 of the second gripper 6b. The structure of the first gripper 6a, which is not shown in FIG. 5, can be substantially similar. The second gripper 6b may also have the indentation 15. The indentation 15 can be oriented towards the first gripper 6a, as shown in FIG. 3.

Together, the first gripper 6a and the second gripper 6b form the gripping device 6, the elongate depressions 14 of the grippers 6a, 6b can be aligned on a straight line, which can correspond to the axis of rotation 7.

The aspects that are not described in more detail in relation to FIG. 5 are similar to the description of FIGS. 3 and 4.

FIG. 6 shows a plan view of the lower gripper part of the second gripper 6b according to FIG. 5. It should be noted that in this illustration the indentation 15 is deeper in the image plane than the depression 14.

The aspects that are not described in more detail in relation to FIG. 6 are similar to the description of FIG. 5 and FIGS. 3 and 4.

FIG. 7 illustrates, in basic form, the overall structure of a stripwound hose 2 with an internal fibre strand 5. Three individual fibres of the fibre strand 5 are shown by way of example. However, this should not be understood to be restrictive. The fibre strand 5 is located within a stripwound hose 2, which is symbolized in FIG. 7 in simplified form by a strip 3 formed into a tubular spiral. The stripwound hose 2 has an inside diameter 2b and has a plurality of turns 4. During the production of a stripwound hose 2, the strip 3 is correspondingly wound up, in FIG. 7 spirally from left to right, which results in the winding direction 9.

FIG. 7 is merely a basic sketch, the stripwound hose 2 being shown without the turns 4 being engaged, in order to simplify the illustration. In this regard, reference should be made to FIG. 8.

FIG. 8 shows a basic illustration, in cross section, of an exemplary stripwound hose 2 with an internal fibre strand 5. Stripwound hoses 2 can be manufactured from profiled strips 3. If this strip 3 is wound up in such a way as has been explained in basic form on the basis of FIG. 7, the resulting turns 4 interlock, each subsequent turn 4 in the winding direction 9 partially overlapping the preceding turn 4. The front end of the stripwound hose 2 is on the left-hand side in FIG. 8, while the rear end of the stripwound hose 2 is on the right-hand side. In the cross-sectional illustration of FIG. 8, the turns 4 are indicated by dotted lines, approximately as they would run as viewed from the outside. The strip 3, which has an S-shaped profile, can be seen in cross section in each case at the upper and the lower boundary of the stripwound hose 2.

FIG. 8 also depicts how the first gripper 6a and the second gripper 6b of an apparatus 1 according to the disclosure can engage on the stripwound hose 2, such as at an interval of two to three turns 4. The portion 2a of the stripwound hose 2 that lies therebetween can then be rotated via the apparatus 1, for example by rotating the first gripper 6a about the axis of rotation 7. Owing to the above-described engagement of the turns 4, the second gripper 6b can retain the stripwound hose 2 upstream of the first gripper 6a as viewed in the winding direction 9, as schematically illustrated in FIG. 8, in order to be able to open the stripwound hose 2.

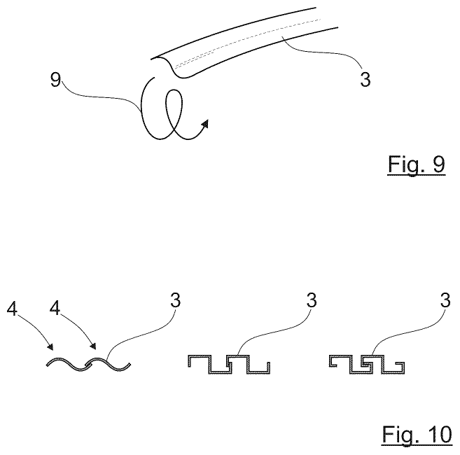

FIG. 9 shows, in basic form, an exemplary profiled strip 3, which has an S-shaped cross section, for a stripwound hose 2. Were this strip 3 to be wound up in the winding direction 9, a stripwound hose 2 according to FIG. 8 could be produced therefrom. Analogously, stripwound hoses 2 can also be manufactured from differently profiled strips 3.

FIG. 10 shows a basic illustration, in cross section, of three exemplary profiles of strips 3 for a stripwound hose 2. Two turns 4 of the strip 3 are shown in each case, in order to illustrate how the turns 4 are interlocked or hook one into another. The left-hand example shows an S-shaped profile similar to FIGS. 8 and 9. The middle and the right-hand example are both a hooked profile. Analogously, many other profiles, i.e. cross sections, are conceivable.

FIGS. 3 to 10 also serve to disclose an method according to the disclosure for opening any desired portion 2a of a stripwound hose 2 which comprises a strip 3 with a plurality of interlocking turns 4 and surrounds an internal fibre strand 5. In this case, at least the following steps are provided:
(a) gripping the stripwound hose 2 at a first holding point and at a second holding point and positioning on an axis of rotation 7 the portion 2a of the stripwound hose 2 that lies between the first holding point and the second holding point;
(b) rotating the first holding point in a first rotational direction 8a about the axis of rotation 7 counter to a winding direction 9 of the stripwound hose 2, in order to at least partially detach the turns 4 of the stripwound hose 2 so that an inside diameter 2b of the stripwound hose 2 on the portion 2a is increased.

The apparatus 1 according to the disclosure can be used to carry out the method according to the disclosure and the method according to the disclosure can be carried out particularly using the apparatus 1 according to the disclosure. However, the apparatus 1 according to the disclosure and the method according to the disclosure can also be used or implemented independently.

It is desirable when, in step (a) of the method according to the disclosure, the first holding point is downstream of the second holding point as viewed in the winding direction 9.

In addition, it is desirable when, in step (a), the stripwound hose 2 is gripped at an interval of two to five, such as three, turns of the stripwound hose 2.

With regard to FIGS. 3 to 6 and FIG. 8, the first holding point can be formed by the first gripper 6a and the second holding point optionally by the second gripper 6b, by correspondingly attaching the grippers 6a, 6b to the stripwound hose 2.

During step (b), the second holding point can be held positionally stably in relation to the axis of rotation 7 or rotated in a second rotational direction 8b about the axis of rotation 7 counter to the first rotational direction 8a.

It has proven to be particularly suitable to, during step (b), rotate the first holding point and the second holding point by 180° to 540°, such as by 270° to 450°, relative to one another.

In the method, a further step may be provided if appropriate:
(c) severing at least one turn 4 of the stripwound hose 2 between the first holding point and the second holding point.

The strip 3 of the stripwound hose 2 can be formed by a metal strip, for example a steel strip. The internal fibre strand 5 can be formed by a fibre optic cable, for example a glass fibre, wherein steps (a) and (b) and, if appropriate, (c) are carried out in such a way that the fibre optic cable or the glass fibre remains undamaged while the stripwound hose 2 is being opened.

In a development of the method, a further step may be provided:
(d) carrying out maintenance and/or repair work on the fibre strand located in the open stripwound hose 2.

Yet a further step may also be provided:
(e) re-closing the stripwound hose 2 by covering the fibre strand 5 in the opened portion 2a of the stripwound hose 2 with a metal cannula, after which the fibre strand 5 and the metal cannula are sheathed with a shrink-fit tube, after which the stripwound hose 2 is closed again, for example crimped together, at the opened portion 2a.

FIGS. 3 to 10 furthermore serve to disclose a method according to the disclosure for the maintenance and/or repair of a fibre strand 5 in any desired portion 2a of a stripwound hose 2, wherein the stripwound hose 2 comprises a strip 3 with a plurality of interlocking turns 4 and the fibre strand 5 is an internal fibre strand 5 surrounded by the stripwound hose 2, wherein the stripwound hose 2 is located for example in a cleanroom environment, in a mask inspection system and/or in a lithography system. In this case, at least the following steps are provided:
(a) gripping the stripwound hose 2 at a first holding point and at a second holding point and positioning on an axis of rotation 7 the portion 2a of the stripwound hose 2 that lies between the first holding point and the second holding point;
(b) rotating the first holding point in a first rotational direction 8a about the axis of rotation 7 counter to a winding direction 9 of the stripwound hose 2, in order to at least partially detach the turns 4 of the stripwound hose 2 so that an inside diameter 2b of the stripwound hose 2 on the portion 2a is increased;
(c) severing at least one turn 4 of the stripwound hose 2 between the first holding point and the second holding point;
(d) carrying out maintenance and/or repair work on the fibre strand located in the open stripwound hose 2;
(e) re-closing the stripwound hose 2 by covering the fibre strand 5 in the opened portion 2a of the stripwound hose 2 with a covering element, such as with a metal cannula, and sheathing it with a shrink-fit tube, after which the stripwound hose 2 is closed again, for example crimped together, at the opened portion 2a.

FIGS. 3 to 10 also serve to disclose the use according to the disclosure of an apparatus 1 according to the disclosure and/or of a method according to the disclosure for opening any desired portion 2a of a stripwound hose 2 and/or of a method according to the disclosure for the maintenance and/or repair of a fibre strand 5 in any desired portion 2a of a stripwound hose 2 according to the description above. The stripwound hose 2 is located in a cleanroom environment and/or in a mask inspection system and/or in a lithography system, for example a projection exposure apparatus 100, 200 for semiconductor lithography, comprising an illumination system 101, 201 with a radiation source 102 and an optical unit 103, 109, 206, which has at least one optical element 116, 118, 119, 120, 121, 122, Mi, 207.

The lithography system in the context of the method according to the disclosure for the maintenance and/or repair of a fibre strand 5 or in the context of the use according to the disclosure may for example be an EUV projection exposure apparatus 100 according to FIG. 1 or a DUV projection exposure apparatus 200 according to FIG. 2, as described above.

### LIST OF REFERENCE SIGNS

1 Apparatus
2 Stripwound hose
2a Portion (of the stripwound hose 2)
2b Inside diameter (of the stripwound hose 2)
3 Strip
4 Turn
5 Fibre strand
6 Gripping device
6a First gripper
6b Second gripper
7 Axis of rotation
8a First rotational direction
8b Second rotational direction
9 Winding direction
10 Inner part
11 Through-passage
12 Outer part
13 Bearing
14 Depression
15 Indentation
16 Groove
17 Screw
100 EUV projection exposure apparatus
101 Illumination system
102 Radiation source
103 Illumination optical unit
104 Object field
105 Object plane
106 Reticle
107 Reticle holder
108 Reticle displacement drive
109 Projection optical unit
110 Image field
111 Image plane
112 Wafer
113 Wafer holder
114 Wafer displacement drive
115 EUV/used/illumination radiation
116 Collector
117 Intermediate focal plane
118 Deflection mirror
119 First facet mirror/field facet mirror
120 First facets/field facets
121 Second facet mirror/pupil facet mirror
122 Second facets/pupil facets
200 DUV projection exposure apparatus
201 Illumination system
202 Reticle stage
203 Reticle
204 Wafer
205 Wafer holder
206 Projection optical unit
207 Lens element
208 Mount
209 Lens housing
210 Projection beam
Mi Mirror

1. An apparatus, comprising:
a gripping device comprising first and second grippers configured to retain a stripwound hose on an axis of rotation of the apparatus,
wherein:
the stripwound hose comprises a strip;
the strip comprises a plurality of interlocking turns surrounding an internal fibre strand;
a portion of the stripwound hose is positionable on the axis of rotation; and
the first gripper is rotatable about the axis of rotation in a first rotational direction counter to a winding direction of the stripwound hose to at least partially detach the interlocking turns of the stripwound hose to increase an inside diameter of the stripwound hose on the portion.

2. The apparatus of claim 1, wherein the first gripper engages the stripwound hose downstream of the second gripper as viewed in the winding direction.

3. The apparatus of claim 1, wherein the first and second grippers are configured to grip the stripwound hose at an interval of from two to five interlocking turns of the stripwound hose.

4. The apparatus of claim 1, wherein:
the second gripper is positionally stable relative to the axis of rotation; and/or
the second gripper is rotatable about the axis of rotation in a second rotational direction, the second rotational direction being counter to the first rotational direction.

5. The apparatus of claim 1, comprising an inner part, an outer part and a bearing, wherein:
the inner part is rotatable about the axis of rotation in the first rotational direction;
the inner part comprises the first gripper and a through-passage for the stripwound hose;
the outer part comprises the second gripper; and
the inner and outer parts are movably connected via the bearing.

6. The apparatus of claim 5, wherein the outer part is connectable to the fixed world, and/or the outer part is rotatable about the axis of rotation in a direction counter to the first rotational direction.

7. The apparatus of claim 1, wherein the first and second grippers are rotatable relative to each other about the axis of rotation by an angle of from 180° to 540°.

8. The apparatus of claim 1, wherein, along a longitudinal direction of the apparatus, the first gripper comprises an elongate depression configured to receive the stripwound hose.

9. The apparatus of claim 1, wherein the second gripper comprises an indentation at an end facing the first gripper.

10. The apparatus of claim 1, further comprising a cutting device configured to sever at least one turn after the stripwound hose has been opened.

11. The apparatus of claim 1, wherein the strip comprises a metal strip.

12. The apparatus of claim 1, wherein the internal fibre strand comprises a fibre optic cable, and the apparatus is configured to open the stripwound hose so that the fibre optic cable is undamaged while the stripwound hose is being opened.

13. A method of opening a portion of a stripwound hose, the stripwound hose comprising a strip, the strip comprising interlocking turns surrounding an internal fibre strand, the method comprising:
(a) gripping the stripwound hose at first and second holding points and positioning the portion on an axis of rotation between the first and second holding points; and
(b) rotating the first holding point about the axis of rotation in a first rotational direction counter to a winding direction of the stripwound hose to at least partially detach the interlocking turns of the stripwound hose to increase an inside diameter of the stripwound hose on the portion of the stripwound hose.

14. The method of claim 13, wherein, during (a), the first holding point is downstream of the second holding point as viewed in the winding direction.

15. The method of claim 13, wherein, during (a), the stripwound hose is gripped at an interval of from two to five interlocking turns of the stripwound hose.

16. The method of claim 13, wherein during (b):
the second holding point is positionally stably relative to the axis of rotation; or
the second holding point is rotated about the axis of rotation in a second rotational direction counter to the first rotational direction.

17. The method of claim 13, wherein, during step, the first and second holding points are rotated relative about the axis of rotation by an angle of rom 180° to 540°.

18. The method of claim 13, further comprising severing at least one turn of the stripwound hose between the first and second holding points.

19. (canceled)

20. The method of claim 13, wherein the strip comprises a metal strip.

21. (canceled)

22. (canceled)

23. A method of maintaining and/or repairing a portion of a fibre strand of a stripwound hose, the stripwound hose comprising a strip, the strip comprising a plurality of interlocking turns surrounding the fibre strand, the method comprising:
(a) gripping the stripwound hose at first and second holding points and positioning the portion on an axis of rotation between the first and second holding points;
(b) rotating the first holding point about the axis of rotation in a first rotational direction counter to a winding direction of the stripwound hose to at least partially detach the interlocking turns of the stripwound hose to increase an inside diameter of the stripwound hose on the portion;
(c) severing at least one interlocking turn of the stripwound hose between the first and second holding points;
(d) performing maintenance and/or repair work on the fibre strand located in the open stripwound hose;
(e) re-closing the stripwound hose by covering the fibre strand in the opened portion of the stripwound hose with a covering element and sheathing it with a shrink-fit tube, after which the stripwound hose is closed again at the opened portion.

24. (canceled)
